(19) United States
(12) Patent Application Publication
(10) Pub. No.: US 2026/0038617 A1
(43) Pub. Date: Feb. 5, 2026

(54) READ DISTURB SCAN USING FAILED BIT COUNT

(71) Applicant: Micron Technology, Inc., Boise, ID (US)

(72) Inventors: Sean Brasfield, Boise, ID (US); Chong Giap Chiew, Santa Clara, CA (US); Tawalin Opastrakoon, Boise, ID (US)

(21) Appl. No.: 18/791,243

(22) Filed: Jul. 31, 2024

(51) Int. Cl. G11C 29/12

(52) U.S. Cl. CPC G11C 29/12005; G11C 2029/1204

(57) ABSTRACT

Methods, systems, and apparatuses include sending a read disturb scan command to a memory device causing the memory device to execute a first read strobe at a lowest read level of a memory portion of the memory device to determine a charge gain value for the memory portion and execute a second read strobe at a highest read level of the memory portion to determine a charge loss value for the memory portion. The charge loss value and the charge gain value are retrieved from the memory device. It is determining that a read disturb for the memory portion satisfies a read disturb threshold using the charge loss value and the charge gain value. The memory portion is flagged for refresh in response to determining that the read disturb satisfies the read disturb threshold.

### TECHNICAL FIELD

The present disclosure generally relates to read disturb scans, and more specifically, relates to read disturb scans using failed bit counts.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 is an example computing system that includes a read disturb scanning component in accordance with some embodiments of the present disclosure.

FIG. 3 is a flow diagram of an example method to perform read disturb scans using failed bit counts in accordance with some embodiments of the present disclosure.

FIG. 4 is another flow diagram of an example method to perform read disturb scans using failed bit counts in accordance with some embodiments of the present disclosure.

FIG. 5 is a block diagram of an example computer system in which embodiments of the present disclosure may operate.

### DETAILED DESCRIPTION

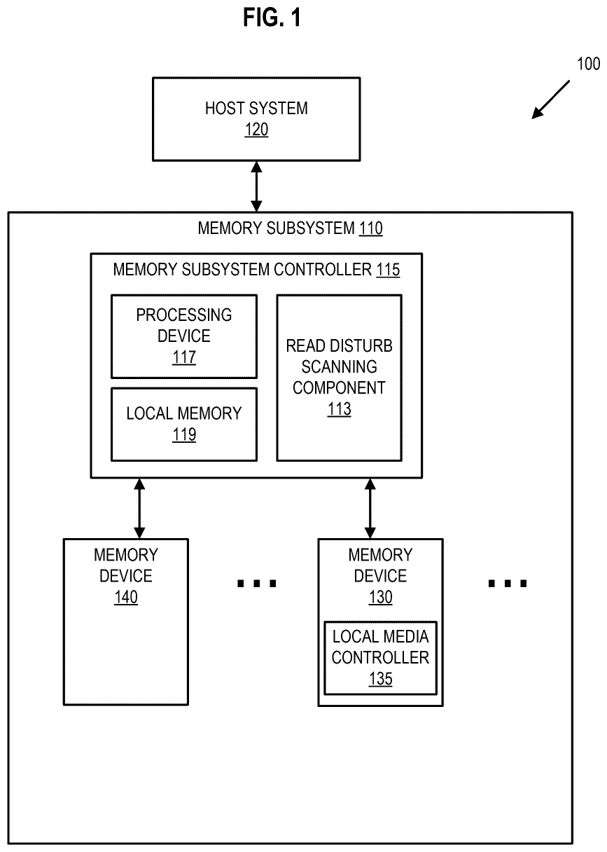

Aspects of the present disclosure are directed to performing read disturb scans using failed bit counts in a memory subsystem. A memory subsystem can be a storage device, a memory module, or a hybrid of a storage device and memory module. Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative-and (NAND) memory device. Other examples of non-volatile memory devices are described below in conjunction with FIG. 1. The dice in the packages can be assigned to one or more channels for communicating with a memory subsystem controller. Each die can consist of one or more planes. Planes can be grouped into logic units identified by a logical unit number (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information, and has various logic states that correlate to the number of bits being stored. The logic states can be represented by binary values, such as “0” and “1”, or combinations of such values. There are various types of cells, such as single-level cells (SLCs), multi-level cells (MLCs), triple-level cells (TLCs), quad-level cells (QLCs), and penta-level cells (PLCs). For example, an SLC can store one bit of information and has two logic states while a QLC can store sixteen bits of information and has sixteen logic states.

In conventional memory systems, memory devices degrade over time. For example, memory cells storing data can lose charge to or gain charge from neighboring cells and the environment, which can result in errors in reading the stored data or a failure to read the stored data altogether. Conventional memory systems address these problems by performing scans to determine the integrity of the stored states of the memory cells. For example, memory subsystems perform multiple reads of the stored data, clock the data out (e.g., copy the data to a register), and determine the raw bit error rate (RBER) by decoding the stored data. These operations include multiple reads (e.g., to determine charge loss as well as charge gain) and a lot of overhead time (e.g., to clock out and decode the data). These operations negatively impact system performance because other operations cannot occur during the long scan time and reduce the quality of service of the memory subsystem because the host system needs to spend time managing the clocking out and decoding of the data.

Aspects of the present disclosure address the above and other deficiencies by performing a single read disturb scan that detects both charge loss and charge gain using a failed bit count (CFbit) for different read levels. For example, the memory subsystem uses a read disturb scan command which causes the memory device to execute read strobes at the least significant bit and most significant bit of a memory cell resulting in the failed bit counts being stored in memory. The memory subsystem can read the failed bit counts for both read strobes from memory without needing to involve the host. Additionally, the memory subsystem can determine the severity of both the charge gain and the charge loss for the memory cell using the failed bit count resulting from the read disturb scan command. Accordingly, the system reduces the time required to perform a read disturb scan to determine charge loss and charge gain and removes the need for host involvement, improving the quality of service for the host.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IOT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processing device such as a processor chipset and a software stack executed by the processor chipset. The processor chipset can include one or more cores, one or more caches, a memory controller (e.g., NVDIMM controller), and/or a storage protocol controller (e.g., a peripheral component interconnect express (PCIe) controller, a serial advanced technology attachment (SATA) controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a SATA interface, including a mini-SATA (mSATA) interface, a PCIe interface, including a mini PCIe (mPCIE) interface, a Non-Volatile Memory Express (NVMe) interface, a universal serial bus (USB) interface, an a Fibre Channel, Serial Attached SCSI (SAS), a Small Computer System Interface (SCSI), a double data rate (DDR) memory bus, a dual in-line memory module (DIMM) interface (e.g., DIMM socket interface that supports Double Data Rate (DDR)), an Advanced Host Controller (AHCI) interface, an Open NAND Flash Interface (ONFI) interface, a Double Data Rate (DDR) interface, a Low Power Double Data Rate (LPDDR) interface, any other interface, and/or combinations of these interfaces. The physical host interface can be used to transmit data between the host system 120 and the memory subsystem 110. The host system 120 can further utilize an NVMe interface to access components (e.g., memory devices 130 and 140) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via the same communication connection, multiple separate communication connections, and/or a combination of communication connections.

The memory devices 130 and 140 can include any combination of the different types of non-volatile memory devices and/or volatile memory devices. The volatile memory devices (e.g., memory device 140) can be, but are not limited to, random-access memory (RAM), such as dynamic random-access memory (DRAM), synchronous dynamic random-access memory (SDRAM), video random-access memory (VRAM), and cache memory.

Some examples of non-volatile memory devices (e.g., memory device 130) include negative-and (NAND) type flash memory devices and write-in-place type memory devices, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random-access memory (FeRAM), magneto random-access memory (MRAM), Spin Transfer Torque (STT)-MRAM, nano-RAM (NRAM), silicon-oxide-nitride-oxide-silicon (SONOS) memory, conductive bridging RAM (CBRAM), resistive random-access memory (RRAM), oxide based RRAM (OxRAM), negative-or (NOR) flash memory, and erasable programmable read-only memory (EPROM), including electrically erasable programmable read-only memory (EEPROM).

A memory subsystem controller 115 (or controller 115 for simplicity) can communicate with the memory devices 130 to perform operations such as reading data, writing data, or erasing data at the memory devices 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The buffer memory of subsystem controller 115 can include any of the volatile or non-volatile memory types mentioned above including combinations thereof. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in memory subsystem 110 (e.g., stored in a local memory 119). In some examples, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processing device or controller separate from the memory subsystem 110).

In general, the memory subsystem controller 115 can receive commands or operations from the host system 120 and can convert the commands or operations into instructions or appropriate commands to achieve the desired access to the memory devices (e.g., memory devices 130 and/or 140). The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA) and/or namespace) and a physical address (e.g., physical block address) that are associated with the memory devices (e.g., memory devices 130 and/or 140). The memory subsystem controller 115 can further include host interface circuitry to communicate with the host system 120 via the physical host interface. The host interface circuitry can convert the commands received from the host system into command instructions to access the memory devices (e.g., memory devices 130 and/or 140) as well as convert responses associated with the memory devices into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices (e.g., memory devices 130 and/or 140).

In some embodiments, the memory devices (e.g., memory devices 130 and/or 140) include local media controllers 135 that operate in conjunction with memory subsystem controller 115 to execute operations on one or more memory cells of the memory devices (e.g., memory devices 130 and/or 140). An external controller (e.g., memory subsystem controller 115) can externally manage the memory devices (e.g., perform media management operations on the memory devices 130 and/or 140). In some embodiments, a memory device (e.g., memory device 130) is a managed memory device, which is a raw memory device combined with a local controller (e.g., local controller 135) for media management within the same memory device package. An example of a managed memory device is a managed NAND (MNAND) device.

The memory subsystem 110 includes a read disturb scanning component 113 that performs read disturb scans to determine charge loss and charge gain. In some embodiments, the controller 115 includes at least a portion of the read disturb scanning component 113. For example, the controller 115 can include a processing device 117 configured to execute instructions stored in local memory 119 for performing the operations described herein. In some embodiments, a read disturb scanning component 113 is part of the host system 120, an application, or an operating system.

The read disturb scanning component 113 performs a read disturb scan to determine both charge loss and charge gain for memory portion of a memory device using a single read disturb scan command and the resulting failed bit counts. Further details with regards to the operations of the read disturb scanning component 113 are described below.

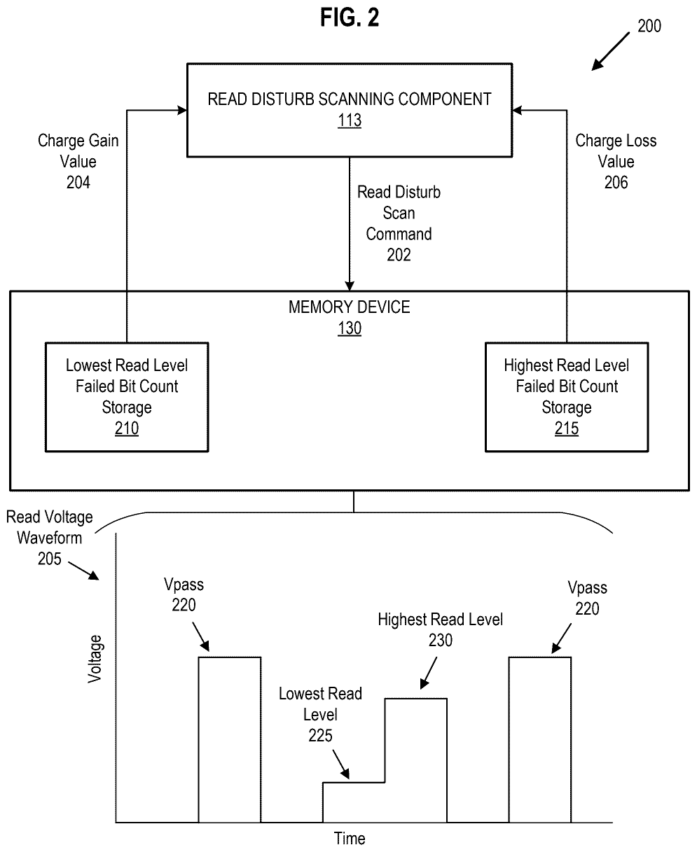

FIG. 2 illustrates an example computing system 200 that includes a read disturb scanning component 113 in accordance with some embodiments of the present disclosure. Computing system 200 also includes memory device 130 which includes lowest read level failed bit count storage 210 and highest read level failed bit count storage 215. Lowest read level failed bit count storage 210 and highest read level failed bit count storage 215 are memory portions within memory device 130 for writing and storing the lowest read level failed bit count and highest read level failed bit count respectively. For example, lowest read level failed bit count storage 210 and highest read level failed bit count storage 215 are in a reserved section of memory device 130 (e.g., a spare area of memory reserved for metadata and/or other operation of memory device 130). In some embodiments, lowest read level failed bit count storage 210 and highest read level failed bit count storage 215 are implemented in volatile memory, e.g., a memory device 140.

As shown in FIG. 2, read disturb scanning component 113 sends read disturb scan command 202 to memory device 130. In some embodiments read disturb scan command 202 includes a unique operation code instructing memory device 130 to enable a failed bit count read operation and execute a read operation using read voltage waveform 205. For example, in response to receive read disturb scan command 202 from read disturb scanning component 113, memory device 130 executes read voltage waveform 205 (e.g., uses read voltage waveform 205 on the memory portion) causing memory device 130 to apply a pass voltage (e.g., Vpass 220) to a memory portion of memory device 130, subsequently apply a read strobe at lowest read level 225 and highest read level 230, and finally apply Vpass 220 again.

In some embodiments, read disturb scan command 202 includes a memory address. For example, read disturb scanning component 113 determines to send read disturb scan command 202 in response to a read count for a memory portion satisfying a read count threshold. In one embodiment, in response to receiving a read command from a host device (e.g., host system 120 of FIG. 1), read disturb scanning component 113 determines a memory address for the read command and determines that a read count for the memory address satisfies a read count threshold (e.g., read count is greater than or equal to the read count threshold). Read disturb scanning component 113 determines to send read disturb scan command 202 including the memory address in response to determining that the read count for the memory address satisfies the read count threshold. In response to receiving read disturb scan command 202 including the memory address, memory device 130 executes the read disturb scan (e.g., applying read voltage waveform 205) to a memory portion of memory device 130 identified by the memory address.

In some embodiments, in response to memory device 130 executing a read strobe at lowest read level 225 of the memory portion, memory device 130 stores the failed bit count for lowest read level 225 in lowest read level failed bit count storage 210. For example, memory device 130 determines the failed bit count for lowest read level 225 as the number of bits that have a voltage higher than lowest read level 225. In one embodiment, memory device 130 determines the failed bit count for lowest read level 225 as the number of memory cells in the memory portion that are read as ‘0’ in response to lowest read level 225. Similarly, in some embodiments, in response to memory device 130 executing a read strobe at highest read level 230 of the memory portion, memory device 130 stores the failed bit count for highest read level 230 in highest read level failed bit count storage 215. For example, memory device 130 determines the failed bit count for highest read level 230 as the number of bits that have a voltage higher than highest read level 230. In one embodiment, memory device 130 determines the failed bit count for highest read level 230 as the number of memory cells in the memory portion that are read as ‘0’ in response to highest read level 230.

Lowest read level 225 corresponds with the lowest read level for memory cells in the memory portion and highest read level 230 corresponds with the highest read level for memory cells in the memory portion. For example, for a TLC memory cell, lowest read level 225 corresponds with read level one (R1) between the first and second memory states and highest read level 230 corresponds with read level seven (R7) between the seventh and eighth memory states. Accordingly, for a TLC memory cell, the failed bit count for lowest read level 225 corresponds with the count of memory cells for the memory portion in all the memory states with the exception of the first memory state (e.g., memory cells in L0 state storing ‘111’). Similarly, for a TLC memory cell, the failed bit count for highest read level 230 corresponds with the count of memory cells for the memory portion in the last memory state (e.g., memory cells in L7 state storing ‘101’).

In some embodiments, in response to memory device 130 completing the read disturb scan (e.g., applying read voltage waveform 205), read disturb scanning component 113 retrieves charge gain value 204 and charge loss value 206 from lowest read level failed bit count storage 210 and highest read level failed bit count storage 215 respectively. For example, read disturb scanning component 113 can send a status request to memory device 130 and retrieve charge gain value 204 and charge loss value 206 in response to memory device 130 responding to the status request with a ready indication (e.g., indicating memory device 130 has completed the read disturb scan and is no longer busy). Alternatively, memory device 130 can pull a ready/busy pin coupled to read disturb scanning component 113 causing read disturb scanning component 113 to retrieve charge gain value 204 and charge loss value 206. In some embodiments, read disturb scanning component 113 receives charge gain value 204 and charge loss value 206 in response to sending read disturb scan command 202.

In some embodiments, read disturb scanning component 113 retrieves a threshold charge gain value and a threshold charge loss value for the memory portion. For example, read disturb scanning component 113 retrieves the threshold charge gain value and the threshold charge loss value from local memory (e.g., local memory 119 of FIG. 1). The threshold charge gain value corresponds with a number of bits expected to be stored above lowest read level 225 (e.g., memory cells in memory states other than the first memory state) and the threshold charge loss value corresponds with a number of bits expected to be stored above highest read level 230 (e.g., memory cells in the last memory state). By way of example, for a memory block composed of TLCs, there is an expectation that each of the memory states includes roughly 18,000 bits and therefore that charge loss value 206 (e.g., failed bit count for highest read level 230) will have a value approximating 18,000. In continuing with the example, there is similarly an expectation that charge gain value 204 (e.g., failed bit count for lowest read level 225) will have a value approximating 126,000 (e.g., 18,000 multiplied by 7). It should be appreciated that this example is meant to be non-limiting. For example, the threshold charge loss and gain values may differ based on the various aspects of the memory subsystem, such as the size of the memory portion concerned, the tolerance of the system for charge loss and gain, and similar variables.

In some embodiments, read disturb scanning component 113 determines whether the read disturb for the memory portion satisfies the read disturb threshold based on comparing charge gain value 204 and charge loss value 206 to threshold charge gain value and threshold charge loss value respectively. For example, read disturb scanning component 113 determines that the read disturb for the memory portion satisfies the read disturb threshold if charge gain value 204 is greater than the threshold charge gain value. This indicates that the voltage distribution for memory cells in the first memory state is shifting right and that some of the memory cells for the first memory state are therefore incorrectly above the lowest read level 225. Similarly, read disturb scanning component 113 determines that the read disturb for the memory portion satisfies the read disturb threshold if charge loss value 206 is less than the threshold charge loss value. This indicates that the voltage distribution for memory cells in the last memory state is shifting left and that some of the memory cells for the last memory state are therefore incorrectly below highest read level 230. As mentioned above, the threshold charge gain and loss values can be set based on the tolerance of the memory subsystem for read disturb. For example, memory subsystems that are not tolerant to read disturb have threshold charge gain and loss values that are very similar to the expected bit distribution (e.g., 18,000 and 126,000 from the example above). In contrast, memory subsystems that are more tolerant to read disturb have threshold charge gain and loss values that are further from the expected bit distribution.

In some embodiments, in response to determining that the read disturb for the memory portion (e.g., memory block) satisfies the read disturb threshold, read disturb scanning component 113 marks the memory portion as having excessive charge loss and/or excessive charge gain. For example, read disturb scanning component 113 flags the memory portion as having excessive charge gain in response to charge gain value 204 exceeding the threshold charge gain value and flags the memory portion as having bad charge loss in response to charge loss value 206 being less than the threshold charge loss value. In some embodiments, read disturb scanning component 113 flags the memory address(es) for a refresh operation in response to the read disturb for the memory portion satisfying the read disturb threshold. For example, read disturb scanning component 113 updates a look-up table for refresh operations and includes the memory addresses for the memory portion (e.g., memory block). In some embodiments, read disturb scanning component 113 performs a refresh operation on the memory addresses for the memory portion in response to flagging the memory addresses for a refresh operation.

In some embodiments, read disturb scanning component 113 updates the read count that triggers a read disturb scan using charge gain value 204 and charge loss value 206. For example, read disturb scanning component 113 compares charge gain value 204 to the threshold charge gain value and compares charge loss value 206 to the threshold charge loss value and adjusts the read count threshold based on the comparison. In one embodiment, as charge gain value 204 increases and gets nearer to the threshold charge gain value, read disturb scanning component 113 reduces the read count threshold resulting in more frequent read disturb scans. Similarly, as charge loss value decreases and gets nearer to the threshold charge loss value, read disturb scanning component 113 reduces the read count threshold.

In some embodiments, read disturb scanning component 113 adjusts the read levels for the memory portion using charge gain value 204 and charge loss value 206. For example, read disturb scanning component 113 compares charge gain value 204 to the threshold charge gain value and compares charge loss value 206 to the threshold charge loss value and adjusts the read levels based on the comparison. In one embodiment, read disturb scanning component 113 increases the read level of lowest read level 225 in response to charge gain value 204 exceeding the threshold charge gain value and/or based on the comparison of charge gain value 204 and the threshold charge gain value (e.g., smaller increase in the read level for more similar charge gain value 204 and threshold charge gain value). Similarly, read disturb scanning component 113 decreases the read level of highest read level 230 in response to charge loss value 206 being less than the threshold charge loss value and/or based on the comparison of charge loss value 206 and the threshold charge loss value. (e.g., smaller increase in the read level for more similar charge loss value 206 and threshold charge loss value).

In some embodiments, read disturb scanning component 113 triggers error avoidance in response to comparing charge loss value 206 and the threshold charge loss value. For example, read disturb scanning component 113 triggers a block family error avoidance bucket update to update the block family to which the memory address belongs in response to charge loss value 206 being less than the threshold charge loss value and/or based on the comparison between charge loss value 206 and the threshold charge loss value.

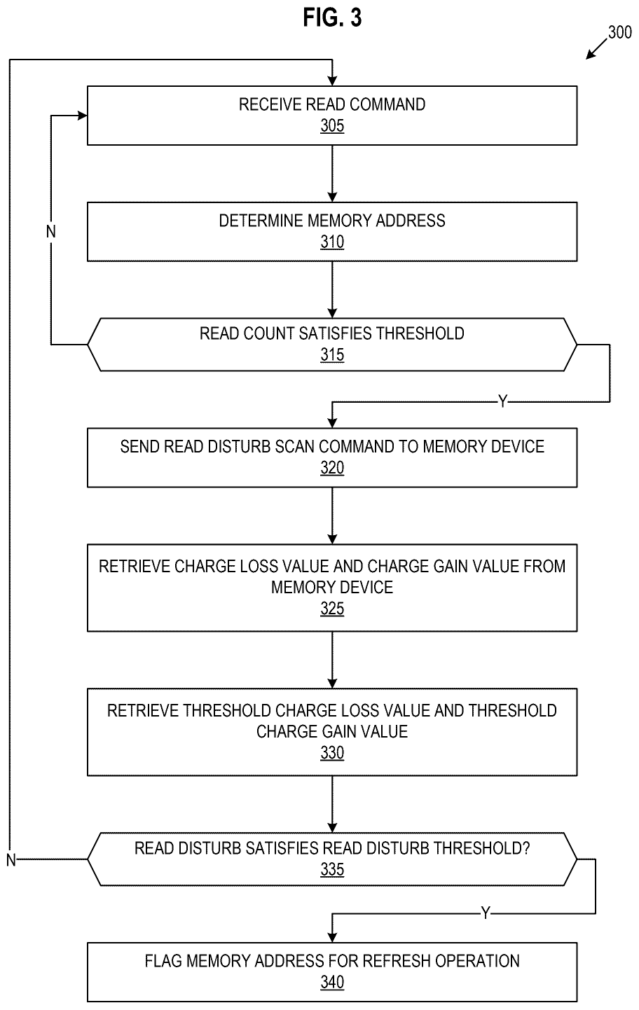

FIG. 3 is a flow diagram of an example method 300 to perform read disturb scans using failed bit counts, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the read disturb scanning component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing device receives a read command. For example, read disturb scanning component 113 receives a read command from a host system (e.g., host system 120 of FIG. 1). In some embodiments, the read command includes a memory address. For example, host system 120 sends read disturb scanning component 113 a read command including a memory address instructing read disturb scanning component 113 to perform a read operation on the memory portion identified by the memory address.

At operation 310, the processing device determines a memory address for the read command. For example, read disturb scanning component 113 receives the read command including a logical address and uses a logical-to-physical look-up table or similar method to determine a physical address for the received logical address.

At operation 315, the processing device determines whether the read count for the memory address satisfies a read count threshold. For example, read disturb scanning component 113 retrieves a read count for the memory address and determines whether the read count exceeds a read count threshold. In some embodiments, the processing device determines a memory portion to which the memory address belong. For example, read disturb scanning component 113 determines a memory block including the address of the received read command and determines whether the read count for that memory block satisfies the read count threshold. If the processing device determines that the read count for the memory address satisfies the read count threshold, the method 300 proceeds to operation 320. If the processing device determines that the read count for the memory address does not satisfy the read count threshold, the method 300 returns to operation 305.

At operation 320, the processing device sends a read disturb scan command to a memory device causing the memory device to execute a read disturb scan to determine a charge loss value and a charge gain value. For example, read disturb scanning component 113 sends read disturb scan command 202 to memory device 130 causing memory device 130 to execute a read disturb scan (e.g., apply read voltage waveform 205 to the memory portion), store the failed bit count for lowest read level 225 (e.g., charge gain value 204) in lowest read level failed bit count storage 210, and store the failed bit count for highest read level 230 (e.g., charge loss value 206) in highest read level failed bit count storage 215. Further details regarding sending the read disturb scan command to the memory device causing the memory device to determine a charge loss value and a charge gain value are described in further detail with reference to FIG. 2.

At operation 325, the processing device retrieves the charge loss value and the charge gain value from the memory device. For example, read disturb scanning component 113 retrieves charge gain value 204 from lowest read level failed bit count storage 210 and retrieves charge loss value 206 from highest read level failed bit count storage 215. In some embodiments, read disturb scanning component 113 retrieves charge gain value 204 and charge loss value 206 in response to receiving a ready response from memory device 130. For example, after executing the read disturb command and storing charge gain value 204 and charge loss value 206 in lowest read level failed bit count storage 210 and highest read level failed bit count storage 215 respectively, memory device 130 pulls a ready pin coupled to read disturb scanning component 113 causing read disturb scanning component 113 to retrieve charge gain value 204 and charge loss value 206. In some embodiments, read disturb scanning component 113 receives charge gain value 204 and charge loss value 206 in response to sending read disturb scan command 202. Further details regarding retrieving the charge loss value and the charge gain value from the memory device are described in further detail with reference to FIG. 2.

At operation 330, the processing device retrieves a threshold charge loss value and a threshold charge gain value. For example, read disturb scanning component 113 retrieves a threshold charge loss value and a threshold charge gain value from local memory (e.g., local memory 119 of FIG. 1). Further details regarding retrieving the threshold charge loss value and the threshold charge gain value are described in further detail with reference to FIG. 2.

At operation 335, the processing device determines whether the read disturb satisfies the read disturb threshold. For example, read disturb scanning component 113 determines whether charge gain value 204 is greater than or equal to the threshold charge gain value and/or determines whether charge loss value 206 is less than or equal to the threshold charge loss value. Further details regarding determining whether the read disturb satisfies the read disturb threshold are described in further detail with reference to FIG. 2. If the processing device determines that the read disturb satisfies the read disturb threshold, the method 300 proceeds to operation 340. If the processing device determines that the read disturb does not satisfy the read disturb threshold, the method 300 returns to operation 305.

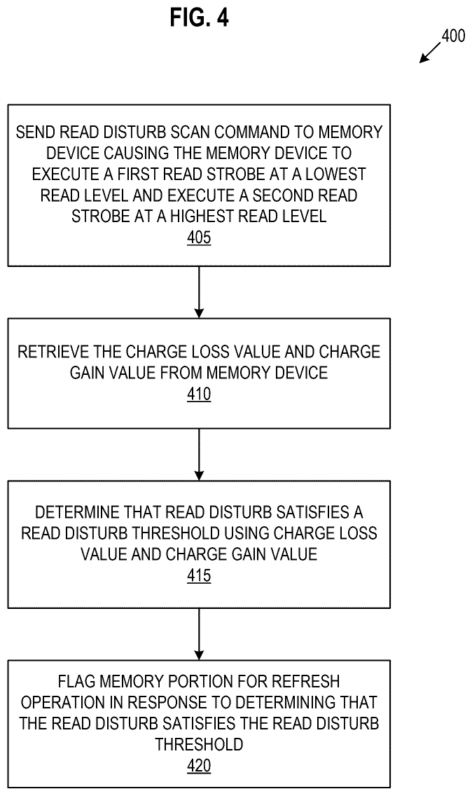

At operation 340, the processing device flags the memory address for a refresh operation. For example, read disturb scanning component 113 updates a look-up table for refresh operations and includes memory addresses of the memory portion. Further details regarding flagging the memory address for a refresh operation are described with reference to FIGS. 2 and 4.

FIG. 4 is a flow diagram of an example method 400 to perform read disturb scans using failed bit counts, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the read disturb scanning component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device sends a read disturb scan command to a memory device causing the memory device to execute a first read strobe at a lowest read level of a memory portion of the memory device and execute a second read strobe at a highest read level of the memory portion. For example, read disturb scanning component 113 sends read disturb scan command 202 to memory device 130 causing memory device to apply a first read strobe at lowest read level 225 and a second read strobe at highest read level 230 to a memory portion of the memory device. Further details regarding sending the read disturb scan command to a memory device causing the memory device to execute a first read strobe at a lowest read level of a memory portion of the memory device and execute a second read strobe at a highest read level of the memory portion are described with reference to FIGS. 2 and 3.

At operation 410, the processing device retrieves the charge loss value and the charge gain value from the memory device. For example, read disturb scanning component 113 retrieves charge gain value 204 from lowest read level failed bit count storage 210 and retrieves charge loss value 206 from highest read level failed bit count storage 215. In some embodiments, read disturb scanning component 113 retrieves charge gain value 204 and charge loss value 206 in response to receiving a ready response from memory device 130. In some embodiments, read disturb scanning component 113 receives charge gain value 204 and charge loss value 206 in response to sending read disturb scan command 202. Further details regarding retrieving the charge loss value and the charge gain value from the memory device are described in further detail with reference to FIGS. 2 and 3.

At operation 415, the processing device determines that the read disturb satisfies a read disturb threshold using the charge loss value and the charge gain value. For example, read disturb scanning component 113 retrieves a threshold charge gain value and a threshold charge loss value from local memory (e.g., local memory 119 of FIG. 1) and determines that the read disturb satisfies the read disturb threshold in response to the charge loss value exceeding the threshold charge loss value (e.g., being greater than or equal to) and/or in response to the charge gain value being less than or equal to the threshold charge gain value. Further details regarding determining that the read disturb satisfies a read disturb threshold using the charge loss value and the charge gain value are described in further detail with reference to FIGS. 2 and 3.

At operation 420, the processing device flags the memory portion for a refresh operation in response to determining that the read disturb satisfies the read disturb threshold. For example, read disturb scanning component 113 updates a look-up table for refresh operations and includes memory addresses of the memory portion. Further details regarding flagging the memory portion for a refresh operation in response to determining that the read disturb satisfies the read disturb threshold are described with reference to FIGS. 2 and 3.

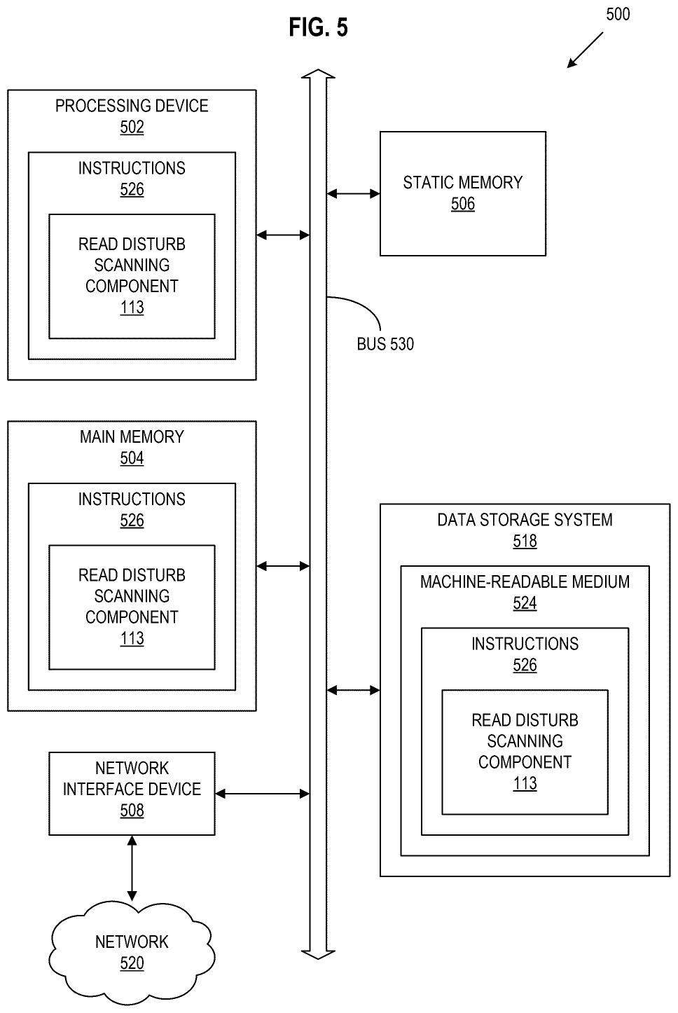

FIG. 5 illustrates an example machine of a computer system 500 within which a set of instructions for causing the machine to perform any one or more of the methodologies discussed herein can be executed. In some embodiments, the computer system 500 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the read disturb scanning component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a smart device, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random-access memory (DRAM) such as synchronous DRAM (SDRAM) or Rambus DRAM (RDRAM), etc.), a static memory 506 (e.g., flash memory, static random-access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526, constituting machine-readable storage media, can also reside, completely or at least partially, within the main memory 504 and/or within the processing device 502 during execution thereof by the computer system 500, the main memory 504 and the processing device 502. The machine-readable storage medium 524, data storage system 518, and/or main memory 504 can correspond to the memory subsystem 110 of FIG. 1.

In one embodiment, the instructions 526 include instructions to implement functionality corresponding to a read disturb scanning component (e.g., read disturb scanning component 113 of FIG. 1). While the machine-readable storage medium 524 is shown in an example embodiment to be a single medium, the term “machine-readable storage medium” should be taken to include a single medium or multiple media that store the one or more sets of instructions (e.g., instructions 526). The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented methods 300 and 400 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random-access memories (RAMs), EPROMs, EEPROMs, magnetic or optical cards, or any type of media suitable for storing electronic instructions coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
sending a read disturb scan command to a memory device of a memory subsystem causing the memory device to:
execute a first read strobe at a lowest read level of a memory portion of the memory device to determine a charge gain value for the memory portion; and
execute a second read strobe at a highest read level of the memory portion to determine a charge loss value for the memory portion;
retrieving the charge loss value and the charge gain value from the memory device;
determining that a read disturb for the memory portion satisfies a read disturb threshold using the charge loss value and the charge gain value; and
flagging the memory portion for refresh in response to determining that the read disturb satisfies the read disturb threshold.

2. The method of claim 1, wherein the charge gain value is a failed bit count for the lowest read level and the charge loss value is a failed bit count for the highest read level.

3. The method of claim 1, further comprising:
retrieving a threshold charge loss value and a threshold charge gain value for the memory portion;
comparing the charge loss value to the threshold charge loss value; and
comparing the charge gain value to the threshold charge gain value, wherein determining that the read disturb for the memory portion satisfies the read disturb threshold comprises:
determining that the read disturb for the memory portion satisfies the read disturb threshold is response to the charge loss value being less than the threshold charge loss value or the charge gain value exceeding the threshold charge gain value.

4. The method of claim 3, wherein the read disturb scan command comprises a memory address for the memory portion and wherein retrieving the threshold charge loss value and the threshold charge gain value for the memory portion uses the memory address.

5. The method of claim 1, further comprising:
determining that a read count for the memory portion satisfies a read count threshold, wherein sending the read disturb scan command is in response to the read count satisfying the read count threshold.

6. The method of claim 5, further comprising:
updating the read count threshold using the charge loss value and the charge gain value.

7. The method of claim 1, further comprising:
determining that the memory portion is flagged for refresh; and
performing a refresh operation on the memory portion in response to determining that the memory portion is flagged for refresh.

8. A non-transitory computer-readable storage medium comprising instructions that, when executed by a processing device, cause the processing device to:
send a read disturb scan command to a memory device of a memory subsystem causing the memory device to:
execute a first read strobe at a lowest read level of a memory portion of the memory device to determine a charge gain value for the memory portion; and
execute a second read strobe at a highest read level of the memory portion to determine a charge loss value for the memory portion;
retrieve the charge loss value and the charge gain value from the memory device;
determine that a read disturb for the memory portion satisfies a read disturb threshold using the charge loss value and the charge gain value; and
flag the memory portion for refresh in response to determining that the read disturb satisfies the read disturb threshold.

9. The non-transitory computer-readable storage medium of claim 8, wherein the charge gain value is a failed bit count for the lowest read level and the charge loss value is a failed bit count for the highest read level.

10. The non-transitory computer-readable storage medium of claim 8, wherein the processing device is further to:
retrieve a threshold charge loss value and a threshold charge gain value for the memory portion;
compare the charge loss value to the threshold charge loss value; and
compare the charge gain value to the threshold charge gain value, wherein determining that the read disturb for the memory portion satisfies the read disturb threshold comprises:
determining that the read disturb for the memory portion satisfies the read disturb threshold is response to the charge loss value being less than the threshold charge loss value or the charge gain value exceeding the threshold charge gain value.

11. The non-transitory computer-readable storage medium of claim 10, wherein the read disturb scan command comprises a memory address for the memory portion and wherein retrieving the threshold charge loss value and the threshold charge gain value for the memory portion uses the memory address.

12. The non-transitory computer-readable storage medium of claim 8, wherein the processing device is further to:
determine that a read count for the memory portion satisfies a read count threshold, wherein sending the read disturb scan command is in response to the read count satisfying the read count threshold.

13. The non-transitory computer-readable storage medium of claim 12, wherein the processing device is further to:
updating the read count threshold using the charge loss value and the charge gain value.

14. The non-transitory computer-readable storage medium of claim 8, wherein the processing device is further to:
determining that the memory portion is flagged for refresh; and
performing a refresh operation on the memory portion in response to determining that the memory portion is flagged for refresh.

15. A system comprising:
a plurality of memory devices; and
a processing device, operatively coupled with the plurality of memory devices, to:
send a read disturb scan command to a memory device of a memory subsystem causing the memory device to:
execute a first read strobe at a lowest read level of a memory portion of the memory device to determine a charge gain value for the memory portion; and
execute a second read strobe at a highest read level of the memory portion to determine a charge loss value for the memory portion;
retrieve the charge loss value and the charge gain value from the memory device;
retrieve a threshold charge loss value and a threshold charge gain value for the memory portion;
compare the charge loss value to the threshold charge loss value;
compare the charge gain value to the threshold charge gain value determine that a read disturb for the memory portion satisfies a read disturb threshold is response to the charge loss value being less than the threshold charge loss value or the charge gain value exceeding the threshold charge gain value; and
flag the memory portion for refresh in response to determining that the read disturb satisfies the read disturb threshold.

16. The system of claim 15, wherein the charge gain value is a failed bit count for the lowest read level and the charge loss value is a failed bit count for the highest read level.

17. The system of claim 15, wherein the read disturb scan command comprises a memory address for the memory portion and wherein retrieving the threshold charge loss value and the threshold charge gain value for the memory portion uses the memory address.

18. The system of claim 15, wherein the processing device is further to:
determine that a read count for the memory portion satisfies a read count threshold, wherein sending the read disturb scan command is in response to the read count satisfying the read count threshold.

19. The system of claim 18, wherein the processing device is further to:
updating the read count threshold using the charge loss value and the charge gain value.

20. The system of claim 15, wherein the processing device is further to:
determining that the memory portion is flagged for refresh; and
performing a refresh operation on the memory portion in response to determining that the memory portion is flagged for refresh.
